(19) United States
(12) Patent Application Publication
(10) Pub. No.: US 2016/0269029 A1
(43) Pub. Date: Sep. 15, 2016

(54) LOGICAL SIGNAL DRIVER WITH DYNAMIC OUTPUT IMPEDANCE AND METHOD THEREOF

(71) Applicant: Realtek Semiconductor Corp., Hsinchu (TW)

(72) Inventors: Gerchih (Joseph) Chou, San Jose, CA (US); Chia-Liang (Leon) Lin, Fremont, CA (US)

(21) Appl. No.: 14/642,887

(22) Filed: Mar. 10, 2015

(51) Int. Cl. H03K 19/0185; H03K 19/094

(52) U.S. Cl. CPC H03K 19/018557; H03K 19/09429

(57) ABSTRACT

In one embodiment, a method comprising receiving a logical signal; driving a source voltage at a first circuit node using a driver circuit in accordance with the logical signal; controlling an output impedance of the driver circuit using a finite state machine (FSM); transmitting the source voltage to a second circuit node via a transmission line; and terminating the second circuit node with a load circuit comprising a data detector.

### BACKGROUND OF THE INVENTION

1. Field of the Invention

The present invention generally relates to transmission of logical signals.

2. Description of Related Art

Persons of ordinary skill in the art understand terms and basic concepts related to microelectronics that are used in this disclosure, such as “voltage,” “current,” “signal,” “load,” “logical signal,” “trip point,” “inverter,” “buffer” “circuit node,” “transmission line,” “characteristic impedance,” “input impedance,” “output impedance,” “MOS (metal oxide semiconductor,” “PMOS (p-channel metal oxide semiconductor),” “NMOS (n-channel metal oxide semiconductor),” “transistor,” “parasitic capacitor,” “AND gate,” and “OR gate.” Terms and basic concepts like these are apparent to those of ordinary skill in the art and thus will not be explained in detail here.

In this disclosure, a logical signal is a signal of two states: “high” and “low,” which can also be re-phrased as “1” and “0.” For brevity, a logical signal in the “high” (“low”) state is simply stated as the logical signal is “high” (“low”), or alternatively, the logical signal is “1” (“0”). Also, for brevity, quotation marks may be omitted and the immediately above is simply stated as the logical signal is high (low), or alternatively, the logical signal is 1 (0), with the understanding that the statement is made in the context of describing a state of the logical signal. A logical signal is embodied by a voltage; the logical signal is “high” (“low”) when the voltage is above (below) an associated trip point of a recipient logical device that receives and processes the logical signal; for brevity, the associated trip point is simply referred to as the trip point of the logical signal. In this disclosure, the trip point of a first logical signal may not be necessarily the same as the trip point of a second logical signal.

If the logical signal is “high” (or “1”) it is said to be “asserted.” If the logical signal is “low,” it is said to be “de-asserted.”

A schematic diagram of a logical signal transmission system 100 is shown in FIG. 1. The system 100 comprises: a driver circuit 110 comprising an inverter 111 for receiving a logical signal D and outputting a source voltage V_{S} to a first circuit node 121; a load 130 comprising a data detector 131 for receiving a load voltage V_{L} from a second circuit node 122; and a transmission line 120 of characteristic impedance Z₀ for providing coupling between the first circuit node 121 and the second circuit node 122. The logical signal D is transmitted by the driver circuit 110 to reach the load 130 via the transmission line 120, resulting in the load voltage V_{L} that is meant to be a representation of an inversion of the logical signal D. To ensure a signal transmission of good quality, the output impedance of the driver circuit 110, denoted as Z_{S} in FIG. 1, is configured to be approximately equal to the characteristic impedance Z₀, and also the input impedance of the load 130, denoted as Z_{L} in FIG. 1, is configured to be approximately equal to the characteristic impedance Z₀. In practice, there are always some parasitic capacitors (not shown in FIG. 1, but obvious to those of ordinary skill in the art) present in the transmission path. Said parasitic capacitors introduce inter-symbol interference and degrade signal integrity for the load voltage V_{L} and adversely increase a probability of error in data detection by the data detector 131.

### BRIEF SUMMARY OF THE INVENTION

In an embodiment, a system comprises: a finite state machine (FSM) configured to receive a logical signal and output a state variable; a driver circuit configured to receive the logical signal and drive a source voltage at a first circuit node with an output impedance controlled by the state variable; a load circuit configured to receive a load voltage at a second circuit node; and a transmission line coupling the first circuit node and the second circuit node. In an embodiment, the FSM works in accordance with a circular round-robin state topology where it sequentially and cyclically goes through a first state, a second state, a third state, and a fourth state, in which the state variable is of a first value, a second value, a third value, and a fourth value, respectively. In an embodiment, the first state is a stable state where, once entered, the FSM stays indefinitely until the logical signal is asserted; the second state is an unstable state where, once entered, the FSM exits after a first predetermined period of time; the third state is a stable state where, once entered, the FSM stays indefinitely until the logical signal is de-asserted; and the fourth state is an unstable state where, once entered, the FSM exits after a second predetermined period of time. In an embodiment, the output impedance is of a first higher impedance, a first lower impedance, a second higher impedance, and a second lower impedance when the state variable is of the first value, the second value, the third value, and the fourth value, respectively, where the second lower impedance is lower than the first higher impedance and the first lower impedance is lower than the second higher impedance. In an embodiment, the first predetermined period of time and the second predetermined period of time are programmable and programmed to be approximately proportional to a unit interval of the logical signal. In an embodiment, a ratio between the first higher impedance and the second lower impedance is programmable and programmed to be approximately proportional to a data rate of the logical signal, and a ratio between the second higher impedance and the first lower impedance is programmable and programmed to be approximately proportional to the data rate of the logical signal. In an embodiment, the driver circuit comprises a first PMOS transistor, a second PMOS transistor, a first NMOS transistor, and a second NMOS transistor, wherein: the first PMOS transistor is turned on when the state variable is of the first value; the first NMOS transistor and the second NMOS transistor are turned on when the state variable is of the second value; the first NMOS transistor is turned on when the state variable is of the third value, and the first PMOS transistor and the second PMOS transistor are turned on when the state variable is of the fourth value.

In an embodiment, a method comprises: receiving a logical signal; driving a source voltage at a first circuit node using a driver circuit in accordance with the logical signal; controlling an output impedance of the driver circuit using a finite state machine (FSM); transmitting the source voltage to a second circuit node via a transmission line; and terminating the second circuit node with a load circuit comprising a data detector. In an embodiment, the FSM works in accordance with a circular round-robin state topology where it sequentially and cyclically goes through a first state, a second state, a third state, and a fourth state, in which the state variable is of a first value, a second value, a third value, and a fourth value, respectively. In an embodiment, the first state is a stable state where, once entered, the FSM stays indefinitely until the logical signal is asserted; the second state is an unstable state where, once entered, the FSM exits after a first predetermined period of time; the third state is a stable state where, once entered, the FSM stays indefinitely until the logical signal is de-asserted; and the fourth state is an unstable state where, once entered, the FSM exits after a second predetermined period of time. In an embodiment, the output impedance is of a first higher impedance, a first lower impedance, a second higher impedance, and a second lower impedance when the state variable is of the first value, the second value, the third value, and the fourth value, respectively, where the second lower impedance is lower than the first higher impedance and the first lower impedance is lower than the second higher impedance. In an embodiment, the first predetermined period of time and the second predetermined period of time are programmable and programmed to be approximately proportional to a unit interval of the logical signal. In an embodiment, a ratio between the first higher impedance and the second lower impedance is programmable and programmed to be approximately proportional to a data rate of the logical signal, and a ratio between the second higher impedance and the first lower impedance is programmable and programmed to be approximately proportional to the data rate of the logical signal. In an embodiment, the driver circuit comprises a first PMOS transistor, a second PMOS transistor, a first NMOS transistor, and a second NMOS transistor, wherein: the first PMOS transistor is turned on when the state variable is of the first value; the first NMOS transistor and the second NMOS transistor are turned on when the state variable is of the second value; the first NMOS transistor is turned on when the state variable is of the third value, and the first PMOS transistor and the second PMOS transistor are turned on when the state variable is of the fourth value.

### BRIEF DESCRIPTION OF THE DRAWINGS

FIG. 1 shows a schematic diagram of a prior art logical signal transmission system.

FIG. 2A shows a schematic diagram of a logical signal transmission system in accordance with an embodiment of the present invention.

FIG. 2B shows a state diagram of the finite state machine in FIG. 2A.

FIG. 2C shows an example timing diagram of the finite state machine in FIG. 2A.

FIG. 3A shows a schematic diagram of a timing circuit suitable for use in the finite state machine of FIG. 2A.

FIG. 3B shows an example timing diagram for the timing circuit of FIG. 3A.

FIG. 3C shows a schematic diagram of a programmable delay inverter suitable for use in the timing circuit of FIG. 3A.

FIG. 4 shows a schematic diagram of a driver circuit suitable for use in the logical transmission system of FIG. 2A.

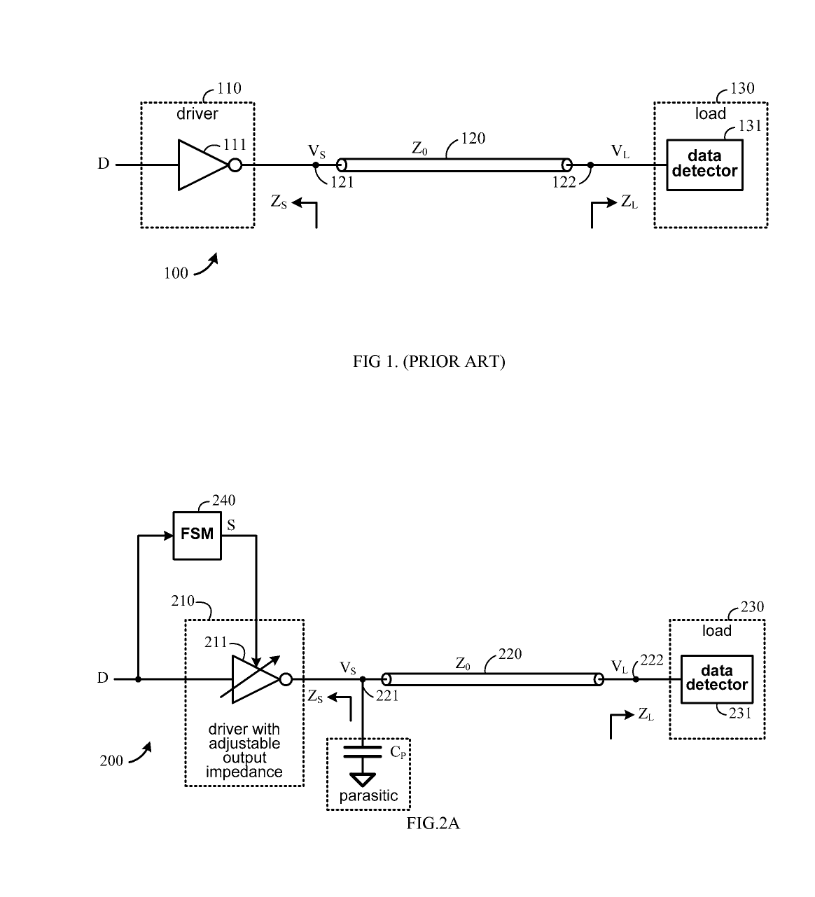

### DETAILED DESCRIPTION OF THE INVENTION

The present invention relates to transmission of logical signals, and in particular, methods and systems for ameliorating logical signal detection by alleviating the degradation of the signal integrity due to undesired parasitic capacitance. An objective of the present invention is to ameliorate logical signal transmission by dynamically adjusting an output impedance of a driver. An objective of the present invention is to ameliorate performance of a logical signal transmission system by conditionally and temporarily reducing an output impedance of a driver. An objective of the present invention is to ameliorate performance of a logical signal transmission system by temporarily reducing an output impedance of a driver upon a logical transition to overcome a slowdown of the logical signal transmission caused by an undesired parasitic capacitor. An objective of the present invention is to ameliorate performance of a logical signal transmission system by temporarily reducing an output impedance of a driver upon a logical transition for a predetermined period of time that is programmable by an amount that is programmable to overcome a slowdown of the logical signal transmission caused by an undesired parasitic capacitor. While the specification describes several example embodiments of the invention considered favorable modes of practicing the invention, it should be understood that the invention can be implemented in many ways and is not limited to the particular examples described below or to the particular manner in which any features of such examples are implemented. In other instances, well-known details are not shown or described to avoid obscuring aspects of the invention.

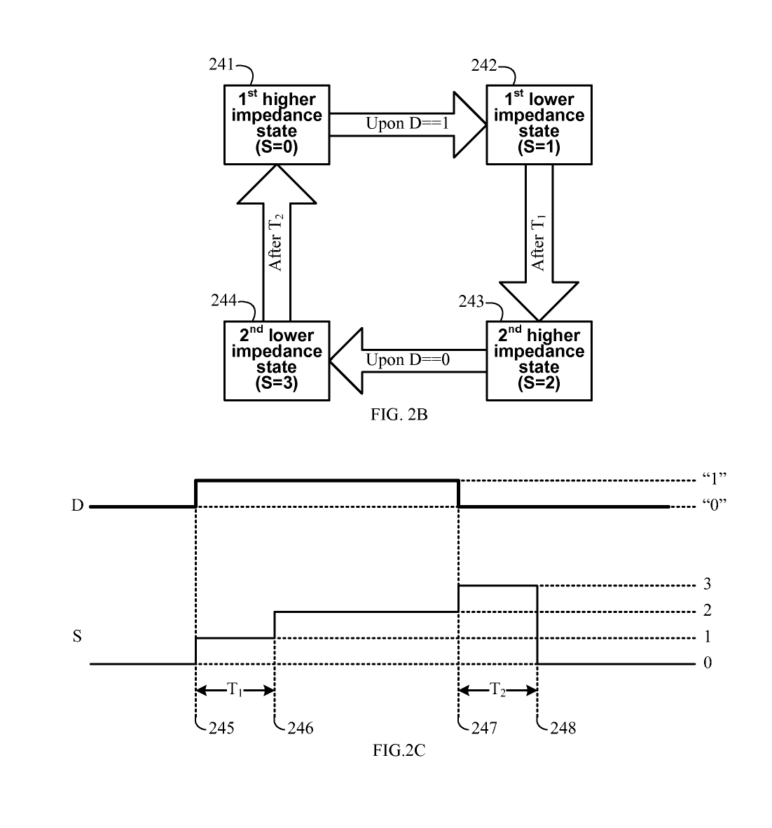

A schematic diagram of a logical signal transmission system 200 in accordance with an embodiment of the present invention is shown in FIG. 2A. The logical signal transmission system 200 comprises: a FSM (finite state machine) 240 for receiving a logical signal D and outputting a state variable S; a driver with adjustable output impedance (hereafter, driver for short) 210 comprising a tunable inverter 211 controlled by the state variable S for receiving the logical signal D and driving a source voltage V_{S} at a first circuit node 221; a load 230 comprising a data detector 231 for receiving a load voltage V_{L} at a second circuit node 222; a transmission line 220 of characteristic impedance Z₀ for providing coupling between the first circuit node 221 and the second circuit node 222. The logical signal D is transmitted by the driver 210 to the load 230 via the transmission line 220, resulting in the load voltage V_{L} that is meant to be a truthful representation of an inversion of the logical signal D. To ensure low reflection at the second circuit node 222, input impedance Z_{L} of the load 230 is configured to be approximately equal to the characteristic impedance Z₀ of the transmission line 220. On the other hand, an output impedance, denoted as Z_{S}, of the driver 210 is dynamically adjusted in accordance with the state variable S instead of being fixed to match the characteristic impedance Z₀ of the transmission line 220. By dynamically adjusting the output impedance Z_{S}, degradation of signal integrity of the source voltage V_{S} in the presence of undesired parasitic capacitors, represented by an equivalent parasitic capacitor C_{P} at the first circuit node 221, can be alleviated.

As far as data detection (by data detector 231) is concerned, an error in detection mostly occurs following a data transition, wherein the data detector fails to resolve the transition. The presence of the parasitic capacitor C_{P}, in particular, slows down the transition of the source voltage V_{S}, and thus makes it more difficult for the data detector to resolve the transition. Reducing the output impedance Z_{S} temporarily upon data transition helps to mitigate the slow down by the parasitic capacitor C_{P} and thus reduces a probability of error in data detection.

FIG. 2B shows a state diagram of FSM 240 of FIG. 2A in accordance with an embodiment. As shown in FIG. 2B, FSM 240 comprises four states: a first higher impedance state 241, a first lower impedance state 242, a second higher impedance state 243, and a second lower impedance state 244, which are associated with a value of the state variable S being 0, 1, 2, and 3, respectively. As shown, the four states 241, 242, 243, and 244 are configured in a circular round-robin topology, and FSM 240 advances sequentially from the first higher impedance state 241 (S=0) to the first lower impedance state 242 (S=1), then to the second higher impedance state 243 (S=2), then to the second lower impedance state 244 (S=3), and then back to the first higher impedance state 241 (S=0), cyclically in an event driven manner. The first higher impedance state 241 and the second higher impedance state 243 are both stable states where, once entered, FSM 240 stays there indefinitely until a respective triggering event occurs. In contrast, the first lower impedance state 242 and the second lower impedance state 244 are both unstable states where, once entered, FSM 240 exits to the second higher impedance state 243 and the first higher impedance state 241 after a first pre-determined period of time T₁ and a second pre-determined period of T₂, respectively. The triggering event for FSM 240 to exit from the first higher impedance state 241 to the first lower impedance state 242 is assertion of the logical signal (D==1); and the triggering event for FSM 240 to exit from the second higher impedance state 243 to the second lower impedance state 244 is de-assertion of the logical signal (D==0).

FIG. 2C shows an exemplary timing diagram for FSM 240. The logical signal D is initially 0, and FSM 240 is initially in the first higher impedance state (S=0). Upon assertion of the logical signal D at timing instant 245, FSM 240 enters the first lower impedance state (S=1), which is an unstable state, where FSM 240 stays for the first pre-determined period of time T₁, after which at timing instant 246 FSM 240 enters the second higher impedance state (S=2). Upon de-assertion of the logical signal D at timing instant 247, FSM 240 enters the second lower impedance state (S=3), which is an unstable state, wherein FSM 240 stays for the second pre-determined period of time T₂, after which at timing instant 248 FSM 240 goes back to the first higher impedance state (S=0). When S=0, S=1, S=2, and S=3, the output impedance of driver 210 (see FIG. 2A) is of a first higher impedance Z_{H1}, a first lower impedance Z_{L1}, a second higher impedance Z_{H2}, and a second lower impedance Z_{L2}, respectively, i.e. Z_{S}=Z_{H1}, Z_{S}=Z_{L1}, Z_{S}=Z_{H2}, and Z_{S}=Z_{L2}, respectively. A transition of the logical signal D comprises a triggering event that causes the FSM 240 to move to an unstable state, in which there is a pre-determined brief period of time where driver 210 has a lower output impedance, which helps to mitigate the hindrance of the transition of the source voltage V_{S} that needs to take place at circuit node 221 (see FIG. 2A) due to the presence of the equivalent parasitic capacitor C_{P}.

Those skilled in the art can freely implement FSM 240 in FIG. 2A in accordance with the state diagram of FIG. 2B and the timing diagram of FIG. 2C per their choices. An exemplary embodiment is described as follows.

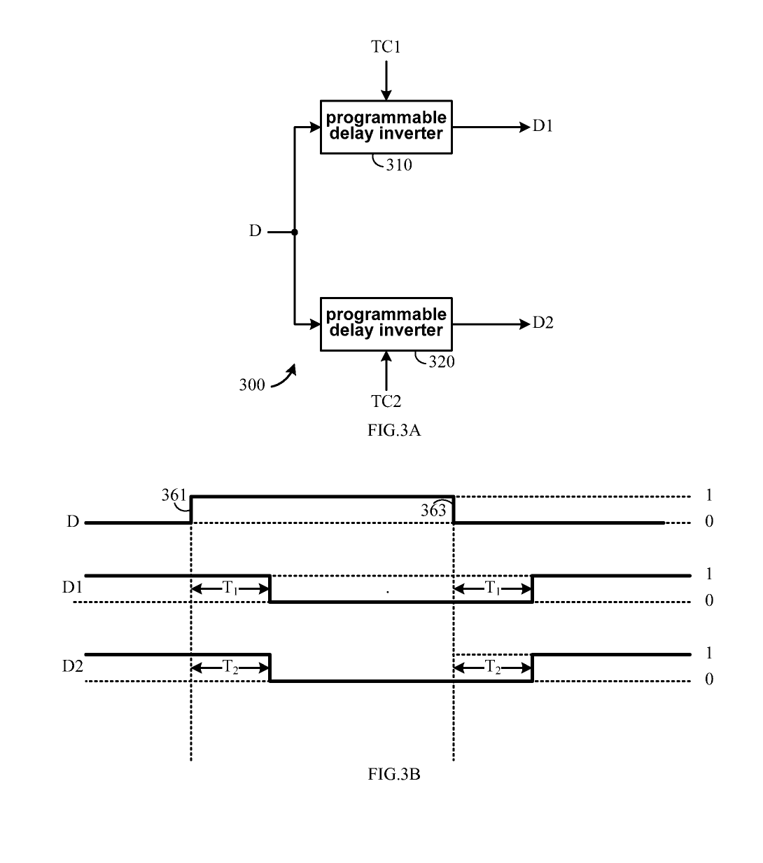

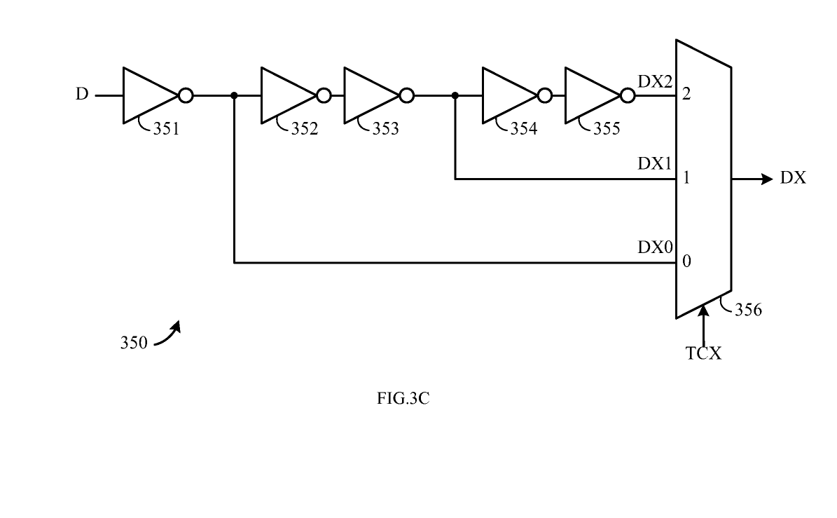

In an embodiment, a timing circuit 300 (of the FSM 240, FIG. 2A) shown in FIG. 3A is used. The timing circuit 300 comprises: a first programmable delay inverter 310 for receiving the logical signal D and outputting a first delayed signal D1 in accordance with a first timing control signal TC1; a second programmable delay inverter 320 for receiving the logical signal D and outputting a second delayed signal D2 in accordance with a second timing control signal TC2. An exemplary timing diagram of the timing circuit 300 of FIG. 3A is shown in FIG. 3B. The circuit delay of the first programmable delay inverter 310 causes a timing difference of T₁ between the logical signal D and the first delay signal D1, where T₁ is controlled by the first timing control signal TC1. The circuit delay of the second programmable delay inverter 320 causes a timing difference of T₂ between the logical signal D and the second delay signal D2, where T₂ is controlled by the second timing control signal TC2. Along with using the timing circuit 300 of FIG. 3A, FSM 240 can be embodied using the truth table tabulated in Table 1.

TABLE 1

| S | D | D1 | D2 |
|---|---|---|---|
| 0 | 0 | X | 1 |
| 1 | 1 | 1 | X |
| 2 | 1 | 0 | X |
| 3 | 0 | X | 0 |

Here, “X” denotes “don't care,” which is well known to those of ordinary skill in the art.

In an embodiment, a schematic of a programmable delay inverter 350 suitable for embodying the programmable delay inverters 310 and 320 of FIG. 3A is depicted in FIG. 3C. By way of example but not limitation, a programmable delay having three programmable values of delay is shown here. Programmable delay inverter 350 comprises cascaded inverters 351˜355 receiving the logical data D and outputting three intermediate signals DX0, DX1, and DX2, and a multiplexer 356 receiving the three intermediate signals DX0, DX1, and DX2 and outputting a multiplexed signal DX in accordance with a control signal TCX, which has three possible values: 0, 1, and 2 for selecting DX0, DX1, and DX2, respectively. When the programmable delay inverter 350 is used for embodying the first programmable delay inverter 310 of FIG. 3A: the control signal TCX is the first timing control signal TC1, and consequently the multiplexed signal DX is the first delay signal D1. When the programmable delay inverter 350 is used for embodying the second programmable delay inverter 320 of FIG. 3A: the control signal TCX is the second timing control signal TC2, and consequently the multiplexed signal DX is the second delay signal D2. In either case, a different value of the control signal TCX leads to selecting a different path from the logical signal D to the multiplexed signal DX and thus a different circuit delay.

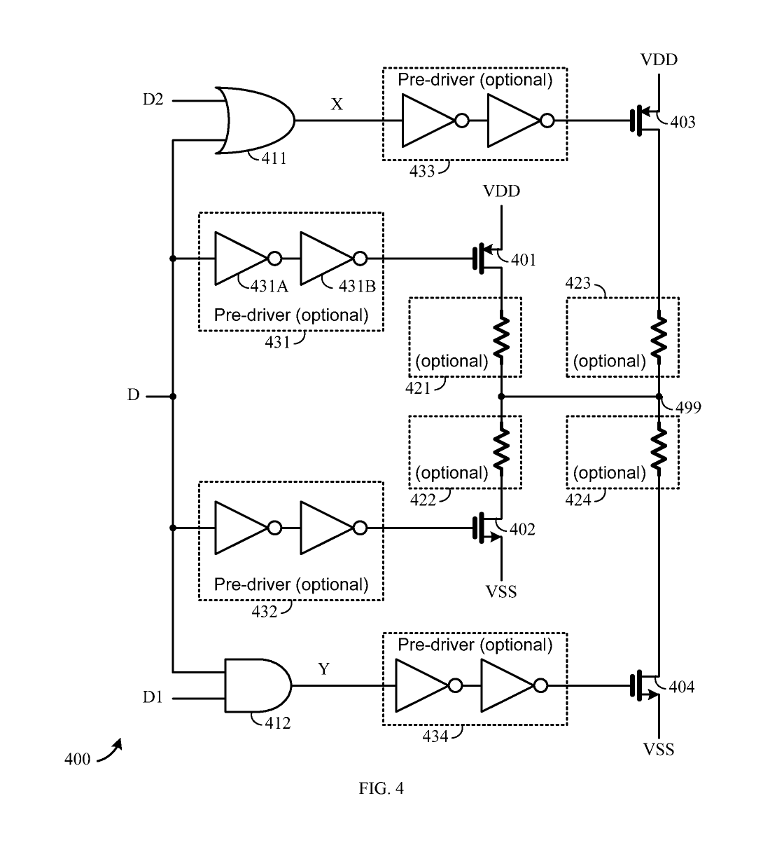

FIG. 4 shows a schematic diagram of a driver 400 suitable for embodying driver 210 of FIG. 2A. Here, the state variable S is based on operations on the logical signal D, the first delayed signal D1, and the second delayed signal D2, as explained earlier and illustrated in FIG. 3A and Table 1. Driver 400 comprises: an OR gate 411 receiving the logical signal D and the second delayed signal D2 and outputting a first intermediate logical signal X; an AND gate 412 receiving the logical signal D and the first delayed signal D1 and outputting a second intermediate logical signal Y; a first PMOS transistor 401 receiving the logical signal D (either directly or optionally through a first pre-driver 431) and driving an output node 499 (either directly or optionally through a first resistor 421); a first NMOS transistor 402 receiving the logical signal D (either directly or optionally through a second pre-driver 432) and driving the output node 499 (either directly or optionally through a second resistor 422); a second PMOS transistor 403 receiving the first intermediate logical signal X (either directly or optionally through a third pre-driver 433) and driving the output node 499 (either directly or optionally through a third resistor 423); and a second NMOS transistor 404 receiving the second intermediate logical signal Y (either directly or optionally through a second pre-driver 434) and driving the output node 499 (either directly or optionally through a second resistor 424). By way of example but not limitation, each of the four optional pre-drivers 431, 432, 433, and 434 comprises two cascaded inverters (for instance, pre-driver 431 comprises two cascaded inverters 431A and 431B). In FIG. 4, “VDD” denotes a power supply node, and “VSS” denotes a ground node; both notations are commonly and widely used in prior art. In terms of interconnection and wiring, FIG. 4 is self-explanatory to those of ordinary skill in the art and thus not described in detail. In an embodiment, circuit node 499 is directly coupled to circuit node 221 of FIG. 2A; in an alternative embodiment, circuit node 499 is coupled to circuit node 221 of FIG. 2A via a serial coupling resistor (not shown in the figure but clear to those of ordinary skill in the art). Note that there are four transistors (i.e. PMOS transistors 401 and 403, and NMOS transistors 402 and 404) that are individually and conditionally turned on to drive the output node 499. Based on the truth table for the state variable S given in Table 1, those of ordinary skill in the art can easily see that, when S=0, only PMOS transistor 401 is turned on; when S=1, both NMOS transistors 402 and 404 are turned on; when S=2, only NMOS transistor 402 is turned on; and when S=3, both PMOS transistors 401 and 403 are turned on. When turned on, a MOS transistor behaves like a resistor of an on-resistance. Let the on-resistance be R_{P1}, R_{N1}, R_{P2}, and R_{N2} for PMOS transistor 401, NMOS transistor 402, PMOS transistor 403, and NMOS transistor 404, respectively. Let the resistance be R_{S1}, R_{S2}, R_{S3}, and R_{S4}, for resistors 421, 422, 423, and 424, respectively. (If an optional resistor is not used, it is equivalent to a resistor of zero resistance.) When S=0, the output impedance of driver 400 is (R_{P1}+R_{S1}), which is previously defined as Z_{H1}; when S=1, the output impedance of driver 400 is (R_{N1}+R_{S2})(R_{N2}+R_{S4})/(R_{N1}+R_{S2}+R_{N2}+R_{S4}), which is previously defined as Z_{L1}; when S=2, the output impedance of driver 400 is (R_{N1}+R_{S2}), which is previously defined as Z_{H2}; when S=3, the output impedance of driver 400 is (R_{P1}+R_{S1})(R_{P2}+R_{S3})/(R_{P1}+R_{S1}+R_{P2}+R_{S3}), which is previously defined as Z_{L2}. Those of ordinary skill in the art can also see that, driver 400 has a higher impedance when S=0 than when S=3, and also has a higher impedance when S=2 than when S=1. That's why S=0 is referred to as a first higher impedance state (where Z_{S}=Z_{H1}), S=1 is referred to as a first lower impedance state (where Z_{S}=Z_{L1}), S=2 is referred to as a second higher impedance state (where Z_{S}=Z_{H2}), and S=3 is referred to as a second lower impedance state (where Z_{S}=Z_{L2}). A ratio between Z_{H1} and Z_{L2} depends on the on-resistance of PMOS transistor 401 plus a resistance of resistor 421, and the on-resistance of PMOS transistor 403 plus a resistance of resistor 423. A ratio between Z_{H2} and Z_{L1} depends on the on-resistance of NMOS transistor 402 plus a resistance of resistor 422, and the on-resistance of NMOS transistor 404 plus a resistance of resistor 424. An on-resistance of a MOS transistor is an equivalent resistance when the MOS transistor is turned on, and is proportional to a width of the MOS transistor, proportional to an over-drive voltage of the MOS transistor, and inversely proportional to a length of the MOS transistor. In an embodiment, resistor 423 is used and embodied by a variable resistor, and therefore Z_{L2} is tunable and can be tuned by tuning the variable resistor 423. In an embodiment, resistor 424 is used and embodied by a variable resistor, and therefore Z_{L1} is tunable and can be tuned by tuning the variable resistor 424. A tunable resistor can be implemented, for instance, using a MOS transistor, the gate of which is controlled by a voltage that determines the on-resistance of the MOS transistor; the principle of using a MOS transistor to implement a variable resistor is well known to those of ordinary skill in the art and thus not described in detail here.

Now refer back to FIG. 2A. FSM 240 dynamically reduces the output impedance of driver 210 to facilitate transitions that need to take place. The signal integrity of the source voltage V_{S} and accordingly the signal integrity of the load voltage V_{L}, are thus improved and less affected by the slowdown due to the parasitic capacitors. Although the dynamic reduction of the output impedance will have an impact on the impedance matching at the first circuit node 221, the impact is temporary and limited to only within a time duration, either the first pre-determined period of time T₁ or the second pre-determined period of time T₂, and therefore can be controlled by carefully determining the time duration and the amount of the reduction of the output impedance.

Note that both the first lower impedance state (S=1) and the second lower impedance state (S=3) are unstable and temporary in nature in response to a transition of the logical signal D. This is because, the degradation of the signal integrity of the source voltage V_{S} due to the parasitic capacitors occurs mainly when the logical signal D undertakes a transition, where a lower output impedance of the driver 210 can help to overcome the hindrance of the parasitic capacitors. The output impedance is temporarily lowered only when a transition of the logical signal D takes place. By making both the first predetermined period of time T₁ and the second predetermined period of time T₂ programmable (e.g., using the first timing control signal TC1 and the second timing control signal TC2 shown in FIG. 3A), and also making an amount of reduction of impedance tunable, for example, by tuning resistors 423 and 424 of FIG. 4 as described earlier, an optimum performance can be achieved.

In an embodiment, the first predetermined period of time T₁ and the second predetermined period of time T₂ are both set to be approximately proportional to a unit interval of the logical signal D.

In an embodiment, the ratio between the first higher impedance Z_{H1} and the second lower impedance Z_{L2} is set to be approximately proportional to a data rate of the logical signal D.

In an embodiment, the ratio between the second higher impedance Z_{H2} and the first lower impedance Z_{L1} is set to be approximately proportional to a data rate of the logical signal D.

In an embodiment, the logical transmission system 200 of FIG. 2A is a part of a DDR (double data rate) synchronous dynamic random access memory PHY that comprises a parallel bus for transmitting a plurality of logical signals concurrently. By way of example but not limitation, the transmission of a first logical signal among said plurality of logical signals is embodied by a first instance of the logical transmission system 200 of FIG. 2A, wherein: the capacitance of the equivalent parasitic capacitor C_{P} is 1 pF, the characteristic impedance Z₀ of transmission line 220 is 50 Ohm, the load impedance Z_{L} is 50 Ohm, both the first predetermined period of time T₁ and the second predetermined period of time T₂ are 250 ps (500 ps), and the four impedances Z_{H1}, Z_{L1}, Z_{H2}, and Z_{L2} are 50, 40, 50, and 40 (50, 45, 50, and 45) Ohm, respectively, when the data rate of the parallel bus is 2000 Mb/s (1000 Mb/s); in the mean while, the transmission of a second logical signal among said plurality of logical signals is embodied by a second instance of the logical transmission system 200 of FIG. 2A, wherein: the capacitance of the equivalent parasitic capacitor C_{P} is 2 pF, the characteristic impedance Z₀ of transmission line 220 is 50 Ohm, the load impedance Z₀ is 50 Ohm, both the first predetermined period of time T₁ and the second predetermined period of time T₂ are 250 ps (500 ps), and the four impedances Z_{H1}, Z_{L1}, Z_{H2}, and Z_{L2} are 50, 30, 50, and 30 (50, 40, 50, and 40) Ohm, respectively, when the data rate of the parallel bus is 2000 Mb/s (1000 Mb/s). In an alternative embodiment, the transmission of the second logical signal among said plurality of logical signals is embodied by a second instance of the logical transmission system 200 of FIG. 2A, wherein: the capacitance of the equivalent parasitic capacitor C_{P} is 2 pF, the characteristic impedance Z₀ of transmission line 220 is 50 Ohm, the load impedance Z₀ is 50 Ohm, both the first predetermined period of time T₁ and the second predetermined period of time T₂ are 400 ps (800 ps), and the four impedances Z_{H1}, Z_{L1}, Z_{H2}, and Z_{L2} are 50, 40, 50, and 40 (50, 45, 50, and 45) Ohm, respectively, when the data rate of the parallel bus is 2000 Mb/s (1000 Mb/s). In other words, the parameters (e.g., T₁, T₂, Z_{H1}, Z_{L1}, Z_{H2}, and Z_{L2}) for each logical signal in the parallel bus can be configured individually.

Those skilled in the art will readily observe that numerous modifications and alterations of the device and method may be made while retaining the teachings of the invention. Accordingly, the above disclosure should be construed as limited only by the metes and bounds of the appended claims.

1. A system, comprising:
a finite state machine (FSM) configured to receive a logical signal and output a state variable;
a driver circuit configured to receive the logical signal and drive a source voltage at a first circuit node with an output impedance controlled by the state variable;
a load circuit configured to receive a load voltage at a second circuit node; and
a transmission line coupling the first circuit node and the second circuit node.

2. The system of claim 1, wherein the FSM works in accordance with a circular round-robin state topology where it sequentially and cyclically goes through a first state, a second state, a third state, and a fourth state, in which the state variable is of a first value, a second value, a third value, and a fourth value, respectively.

3. The system of claim 2, wherein: the first state is a stable state where, once entered, the FSM must stay indefinitely until the logical signal is asserted; the second state is an unstable state where, once entered, the FSM must exit after a first predetermined period of time; the third state is a stable state where, once entered, the FSM must stay indefinitely until the logical signal is de-asserted; and the fourth state is an unstable state where, once entered, the FSM must exit after a second predetermined period of time.

4. The system of claim 3, wherein: the output impedance is of a first higher impedance, a first lower impedance, a second higher impedance, and a second lower impedance when the state variable is of the first value, the second value, the third value, and the fourth value, respectively, where the second lower impedance is lower than the first higher impedance and the first lower impedance is lower than the second higher impedance.

5. The system of claim 4, wherein the first predetermined period of time and the second predetermined period of time are programmable and programmed to be approximately proportional to a unit interval of the logical signal.

6. The system of claim 5, wherein a ratio between the first higher impedance and the second lower impedance is programmable and programmed to be approximately proportional to a data rate of the logical signal, and a ratio between the second higher impedance and the first lower impedance is programmable and programmed to be approximately proportional to the data rate of the logical signal.

7. The system of claim 6, wherein: the driver circuit comprises a first PMOS transistor, a second PMOS transistor, a first NMOS transistor, and a second NMOS transistor, wherein: the first PMOS transistor is turned on when the state variable is of the first value; the first NMOS transistor and the second NMOS transistor are turned on when the state variable is of the second value; the first NMOS transistor is turned on when the state variable is of the third value, and the first PMOS transistor and the second PMOS transistor are turned on when the state variable is of the fourth value.

8. A method, comprising:
receiving a logical signal;
driving a source voltage at a first circuit node using a driver circuit in accordance with the logical signal;
controlling an output impedance of the driver circuit using a finite state machine (FSM);
transmitting the source voltage to a second circuit node via a transmission line; and
terminating the second circuit node with a load circuit comprising a data detector.

9. The method of claim 8, wherein the FSM works in accordance with a circular round-robin state topology where it sequentially and cyclically goes through a first state, a second state, a third state, and a fourth state, in which the state variable is of a first value, a second value, a third value, and a fourth value, respectively.

10. The method of claim 9, wherein: the first state is a stable state where, once entered, the FSM must stay indefinitely until the logical signal is asserted; the second state is an unstable state where, once entered, the FSM must exit after a first predetermined period of time; the third state is a stable state where, once entered, the FSM must stay indefinitely until the logical signal is de-asserted; and the fourth state is an unstable state where, once entered, the FSM must exit after a second predetermined period of time.

11. The method of claim 10, wherein: the output impedance is of a first higher impedance, a first lower impedance, a second higher impedance, and a second lower impedance when the state variable is of the first value, the second value, the third value, and the fourth value, respectively, where the second lower impedance is lower than the first higher impedance and the first lower impedance is lower than the second higher impedance.

12. The method of claim 11, wherein the first predetermined period of time and the second predetermined period of time are programmable and programmed to be approximately proportional to a unit interval of the logical signal.

13. The method of claim 12, wherein a ratio between the first higher impedance and the second lower impedance is programmable and programmed to be approximately proportional to a data rate of the logical signal, and a ratio between the second higher impedance and the first lower impedance is programmable and programmed to be approximately proportional to the data rate of the logical signal.

14. The method of claim 13, wherein: the driver circuit comprises a first PMOS transistor, a second PMOS transistor, a first NMOS transistor, and a second NMOS transistor, wherein: the first PMOS transistor is turned on when the state variable is of the first value; the first NMOS transistor and the second NMOS transistor are turned on when the state variable is of the second value; the first NMOS transistor is turned on when the state variable is of the third value, and the first PMOS transistor and the second PMOS transistor are turned on when the state variable is of the fourth value.

15. A method, comprising:
receiving a logical signal at circuitry including an adjustable driver and a parasitic capacitor; and
responsive to a transition of the logical signal, mitigating effects by the parasitic capacitor on a speed of the transition by temporarily reducing an output impedance of the adjustable driver according to a predetermined time period.

16. The method of claim 15, wherein reducing is based on providing a first state variable from a finite state machine (FSM) to the adjustable driver.

17. The method of claim 16, further comprising changing the output impedance of the adjustable driver immediately after the predetermined time period elapses, the changing based on a second state variable received at the adjustable driver.

18. The method of claim 17, wherein the second state variable corresponds to a higher output impedance of the adjustable driver than the output impedance corresponding to the first state variable.

19. The method of claim 16, wherein the FSM comprises a programmable delay inverter.

20. The method of claim 15, further comprising outputting by the adjustable driver a source voltage, based on the logical signal, over a transmission line to a data detector, the data detector resolving the transition with less error than a source voltage provided over the transmission line at a higher adjustable driver output impedance.
